(19) United States
(12) Patent Application Publication
(10) Pub. No.: US 2015/0282378 A1
(43) Pub. Date: Oct. 1, 2015

(54) INDUCTION DEVICE AND ELECTRONIC DEVICE

(71) Applicants: HONG FU JIN PRECISION INDUSTRY (ShenZhen) CO., LTD, Shenzhen (CN); HON HAI PRECISION INDUSTRY CO., LTD., New Taipei (TW)

(72) Inventors: YING GAO, Shenzhen (CN); ZHEN-LEI LI, Shenzhen (CN); CHUNG-CHENG HSIEH, New Taipei (TW); XIU-ZHONG YIN, Shenzhen (CN)

(21) Appl. No.: 14/525,742

(22) Filed: Oct. 28, 2014

(30) Foreign Application Priority Data
Mar. 26, 2014 (CN) 201410115577.7

(51) Int. Cl. H05K 7/18

(52) U.S. Cl. CPC H05K 7/183

(57) ABSTRACT

An induction device includes a frame, a first conductive assembly, and a sliding assembly. The frame is configured to be secured to a rack. The first conductive assembly is located in the frame. The sliding assembly is mounted in the frame and includes a second conductive assembly. The second conductive assembly is slidable relative to the frame and electronically couples to the first conductive assembly during sliding, and the second conductive assembly is configured to electronically couple to a detection module during sliding. An electronic device with the induction device is further disclosed.

### FIELD

The subject matter herein generally relates to an induction device and an electronic device with the induction device.

### BACKGROUND

An electronic device, such as a server, is generally secured to a rack. Generally, a detection module is secured to the rack and configured to detect running states of the server, an induction module is secured to the server and electronically coupled to the detection module and a computer, to transmit the running states to the computer.

### BRIEF DESCRIPTION OF THE DRAWINGS

Implementations of the present technology will now be described, by way of example only, with reference to the attached figures.

FIG. 1 is an isometric view of an embodiment of an electronic device.

FIG. 2 is an exploded, isometric view of an embodiment of an induction device of the electronic device of FIG. 1.

FIG. 3 is similar to FIG. 2, but viewed from a different angle.

FIG. 4 is an assembled, isometric view of a sliding assembly of the induction device of FIG. 1.

FIG. 5 is a diagrammatic view of the sliding assembly from FIG. 4 in a first state.

FIG. 6 is similar to FIG. 5, but showing the sliding assembly in a second state.

FIG. 7 is also similar to FIG. 5, but showing the sliding assembly in a third state.

FIG. 8 is an exploded, isometric view of the sliding assembly from FIG. 4.

FIG. 9 is an isometric view of a mounting plate of the sliding assembly from FIG. 8.

FIG. 10 is an assembled, isometric view of the induction device from FIG. 2.

FIG. 11 is a front view of the induction device from FIG. 10.

FIG. 12 is a cross sectional view of the induction device from FIG. 11, taken along a line XII-XII.

FIG. 13 is a cross sectional view of the induction device from FIG. 10, taken along a line XIII-XIII.

FIG. 14 is another sectional view of the induction device from FIG. 10 with the sliding assembly in the first state, taken along a line XIV-XIV.

FIG. 15 is similar to FIG. 14, but showing the sliding assembly in the second state.

FIG. 16 is also similar to FIG. 14, but showing the sliding assembly in the third state.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising,” when utilized, means “including, but not necessarily limited to”; it specifically indicates open-ended inclusion or membership in the so-described combination, group, series and the like.

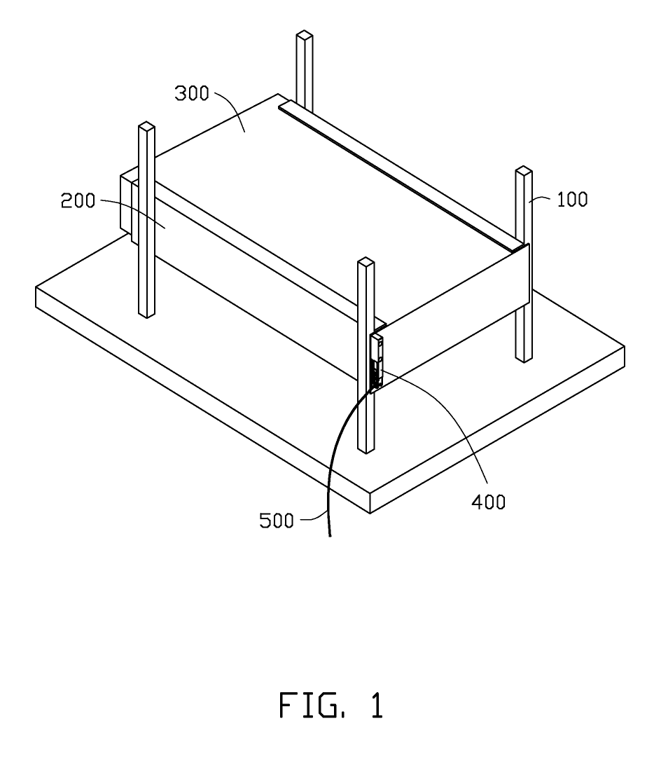

FIG. 1 illustrates an electronic device in accordance with an embodiment. The electronic device includes a rack 100, a guiding rail 200 secured to the rack 100, and a server 300 secured to the guiding rail 200. A detection module (not shown) is located in the guiding rail 200. An induction device 400 is attached to the server 300 and coupled to a host (not shown) via a cable 500.

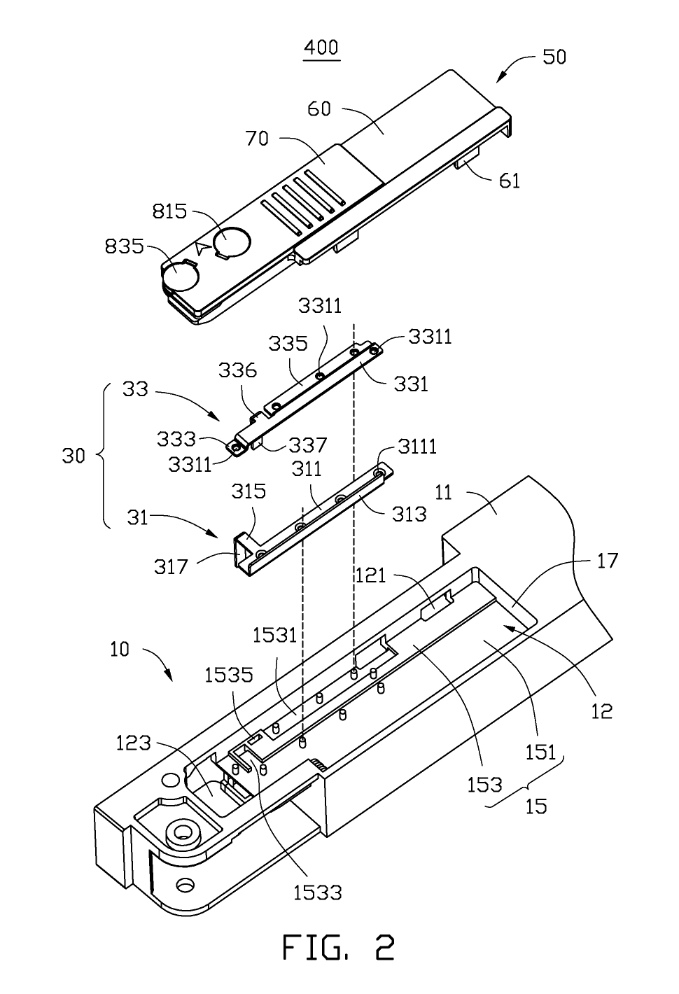

FIG. 2 illustrates that the induction device 400 can include a frame 10, a first conductive assembly 30 mounted to the frame 10, and a sliding assembly 50. The sliding assembly 50 can be latched to the frame 10.

The first conductive assembly 30 can include a first resilient piece 31 and a second resilient piece 33. The first resilient piece 31 includes a first piece body 311, a first coupling portion 313 extending from a first edge of the first piece body 311, a first extension piece 315 extending from a second edge, opposite to the first edge, of the first piece body 311, and a first connecting piece 317 extending from the first extension piece 315. The first piece body 31 defines a first mounting hole 3111. In at least one embodiment, the first coupling portion 313 is a rectangular piece, and each of the first coupling portion 313 and the first connecting piece 317 is substantially perpendicular to the first piece body 311.

The second resilient piece 33 includes a second piece body 331, a mounting piece 333 extending from a first edge of the second piece body 331, a mounting wall 335 and a second extension piece 336 extending from a second edge, adjacent to the first edge, of the second piece body 331, and a second connecting piece 337 extending from the second extension piece 336. Each of the second piece body 33 and the mounting piece 333 defines a second mounting hole 3311. In at least one embodiment, the second coupling portion 333 is a rectangular piece, the second connecting piece 337 is substantially perpendicular to the second piece body 331, and the second connecting piece 337 is coplanar with the mounting wall 335.

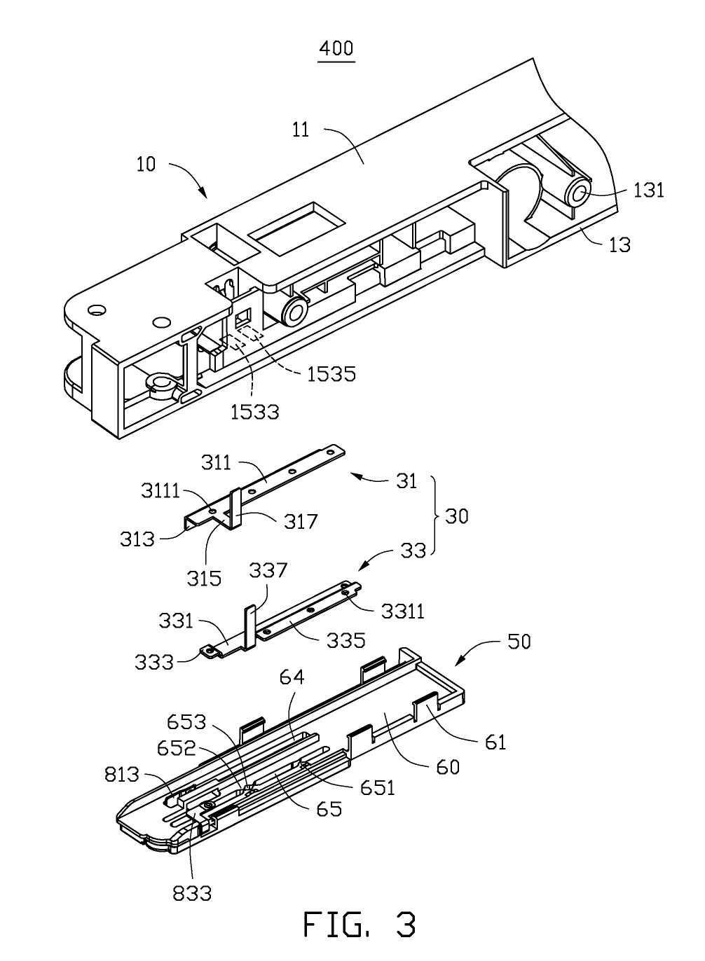

FIGS. 2 and 3 illustrate that the frame 10 can include a top plate 11 and a side plate 13 substantially perpendicularly to the top plate 11. The side plate 13 defines a plurality of mounting holes 131. The top plate 11 defines a recess portion 12 for receiving the sliding assembly 50. The recess portion 12 has a bottom wall 15 and a sidewall 17 substantially perpendicularly to the bottom wall 15. A plurality of mounting posts 18 extend from the bottom wall 15. The bottom wall 15 is stepped and includes a first wall piece 151 configured to position the first resilient piece 31 and a second wall piece 153 configured to position the second resilient piece 33. The second wall piece 153 protrudes from the first wall piece 151.

The second wall piece 153 defines a slot 1531 for the mounting wall 335, a first inserting hole 1533 for the first connecting piece 317, and a second inserting hole 1535 for the second connecting piece 337. A plurality of mounting posts 18 is located in the slot 1531 corresponding to the plurality of second mounting holes 3311.

The recess portion 12 defines a latching hole 121 extending from the bottom wall 15 to the sidewall 17. The recess portion 12 further defines a recess slot 123.

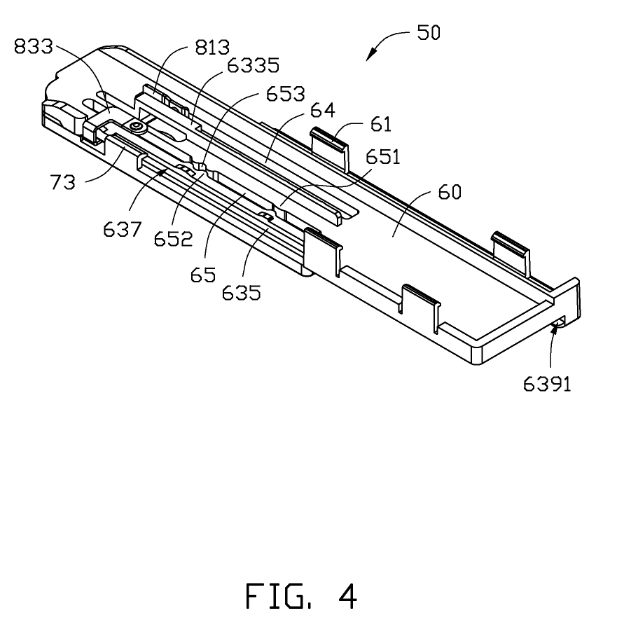

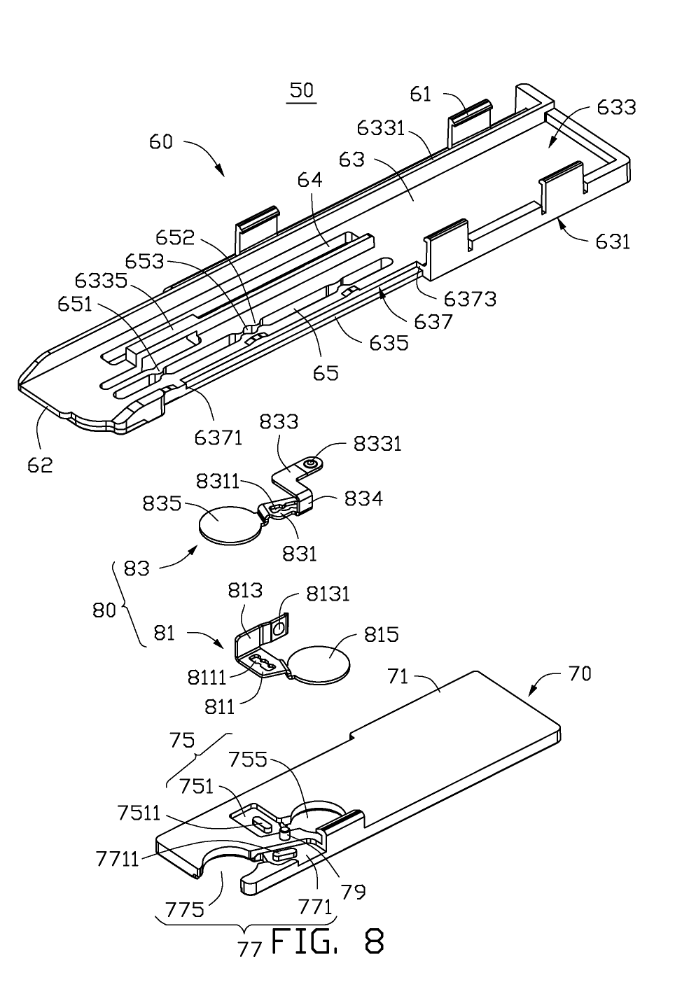

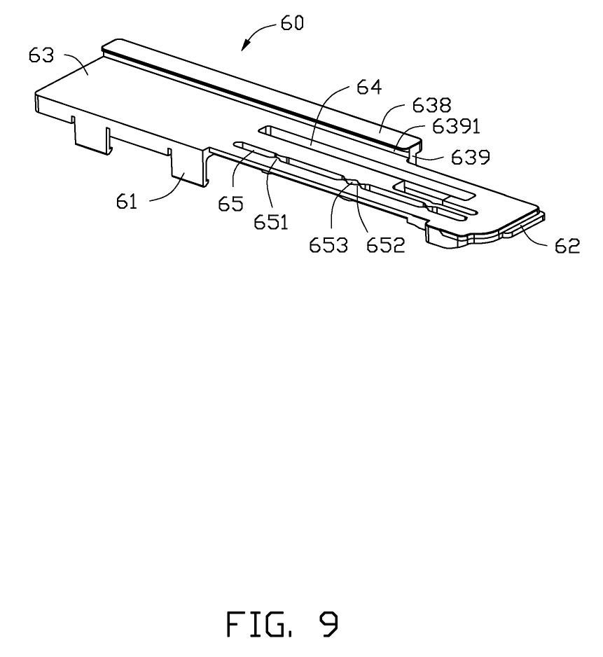

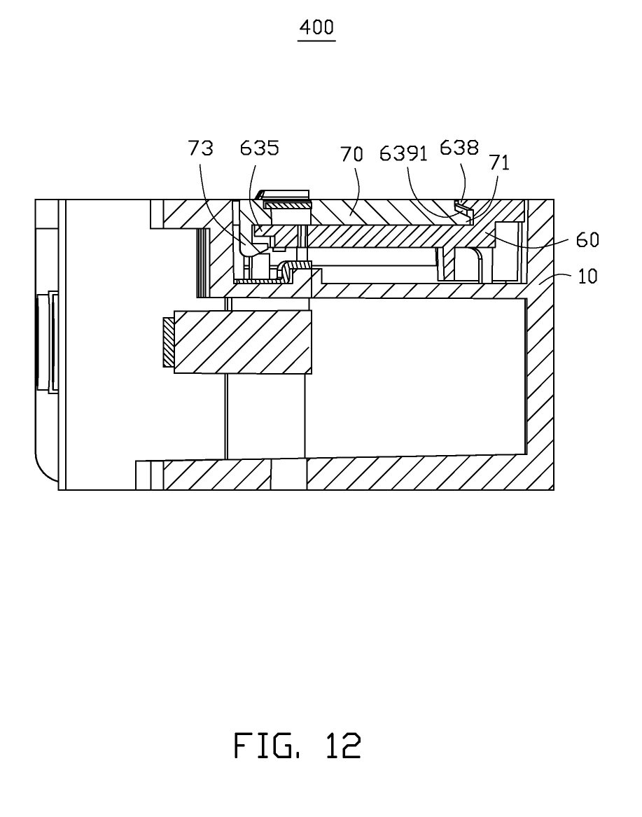

Referring to FIGS. 4, 8, 9, and 12, the sliding assembly 50 can include a mounting plate 60, a sliding member 70, and a second conductive assembly 80. The second conductive assembly 80 is slidable relative to the mounting plate 60 with the sliding member 70. The second conductive assembly 80 can include a first elastic piece 81 and a second elastic piece 83.

The mounting plate 60 comprises a plate body 63, a plurality of latching portions 61 and a blocking piece 62 extending from the plate body 63. The plate body 63 defines a first sliding slot 64 and a second sliding slot 65 substantially parallel to the first sliding slot 64. A pair of first blocking portions 651 extends from opposite edges of the second sliding slot 65 in each end of the second sliding slot 65. Two pairs of second blocking portions 652 extend from opposite edges of the second sliding slot 65 between the two pairs of first blocking portions 651. A receiving portion 653 is defined between the two pairs of second blocking portions 652. In at least one embodiment, the receiving portion 653 is circular, and each first blocking portion 651 and each second blocking portion 653 is a curved protrusion in the second sliding slot 65.

The plate body 63 has a top surface 631 and a bottom surface 633 and defines a guiding slot 637 to form a guiding piece 635. The guiding slot 637 has a first end 6371 and a second end 6373. A plurality of holding walls 6331 extends from the bottom surface 633. A pressing portion 6335 extends from the bottom surface 633 between the first sliding slot 64 and the second sliding slot 65. The holding walls 6331 are substantially parallel to the first sliding slot 64. A blocking plate 638 extends from the top surface 631 and is substantially parallel to the plate body 63. The blocking plate 638 is connected to the mounting plate 60 via a connecting plate 639. A sliding slot 6391 is defined cooperatively by the blocking plate 638, the connecting plate 639, and the plate body 63, for the sliding member 70 sliding along.

The first elastic piece 81 can include a first installation piece 811, a first connecting piece 813 extending from a first end of the first installation piece 811, and a first coupling piece 815 extending from a second end of the first installation piece 811. The first installation piece 811 defines a first installation slot 8111. A first protrusion 8131 protrudes from the first connecting piece 813. In at least one embodiment, the first coupling piece 815 is substantially parallel to the first installation piece 811, and the first connecting piece 813 is substantially perpendicular to the first installation piece 811.

The second elastic piece 83 can include a second installation piece 831, a second connecting piece 833 substantially parallel to the second installation piece 831, and a second coupling piece 835 extending from an edge of the second installation piece 831. The second installation piece 831 defines a second installation slot 8311. A second protrusion 8331 protrudes from the second connecting piece 833. The second connecting piece 833 is connected to the second installation piece 831 via a piece 834. In at least one embodiment, the second coupling piece 835 is substantially parallel to the second installation piece 831.

The sliding member 70 can include a sliding portion 71 and a limiting portion 73.

The sliding portion 71 is slidable in the sliding slot 6391. The limiting portion 73 can be engaged with the guiding piece 635 and is slidable in the guiding slot 637. In at least one embodiment, the sliding portion 71 is a rectangular piece, and the limiting portion 73 is a hook. The sliding member 70 defines a first receiving portion 75 configured to receive the first elastic piece 81 and a second receiving portion 77 configured to receive the second elastic piece 83. A sliding post 79 extends between the first receiving portion 75 and the second receiving portion 77. The sliding post 79 is slidable in the second sliding slot 65.

The first receiving portion 75 can include a first inserting slot 751 and a first through slot 755. The first coupling piece 815 can be inserted through the first through hole 755 to electronically couple to the detection module. A first mounting rib 7511 extends in the first inserting slot 751 corresponding to the first installation slot 8111.

The second receiving portion 77 can include a second inserting slot 771 and a second through slot 775. The second coupling piece 815 can be inserted through the second through hole 775 to electronically couple to the detection module. A second mounting rib 7711 extends in the second inserting slot 771 corresponding to the second installation slot 8311.

In assembly of the induction device 400, the first installation piece 811 is inserted into the first inserting slot 751, the first coupling piece 815 is inserted into the first through slot 755, and the first mounting rib 7511 is mounted in the first installation slot 8111. The second installation piece 831 is inserted into the second inserting slot 751, the second coupling piece 835 is inserted into the second through slot 755, and the second mounting rib 7711 is mounted in the second installation slot 8311. Thus, the first elastic piece 81 and the second elastic piece 83 are secured to the sliding member 70. The sliding portion 71 is inserted into the sliding slot 6391, the limiting portion 73 is engaged with the guiding piece 635, and the sliding post 79 are received in the second sliding slot 65. The top surface 631 resists the first installation piece 811 and the second installation piece 831. The first connecting piece 813 is received in the first sliding slot 64. The second connecting piece 833 and the second installation 831 are located in opposite sides of the plate body 63. Thus, the sliding assembly is assembled completely.

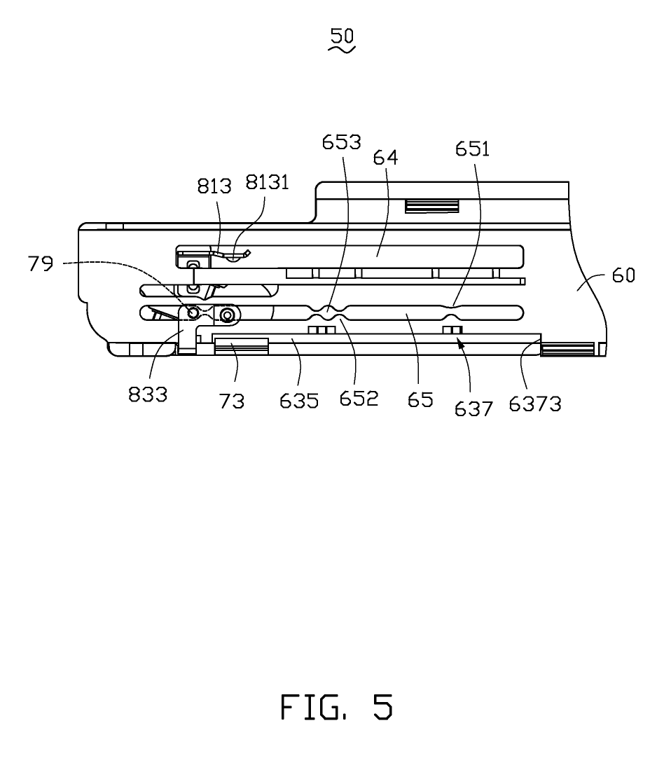

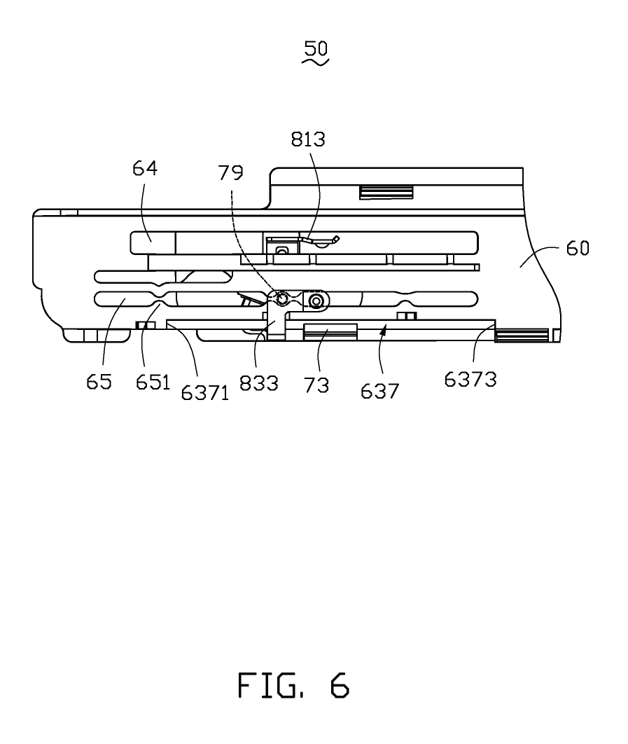

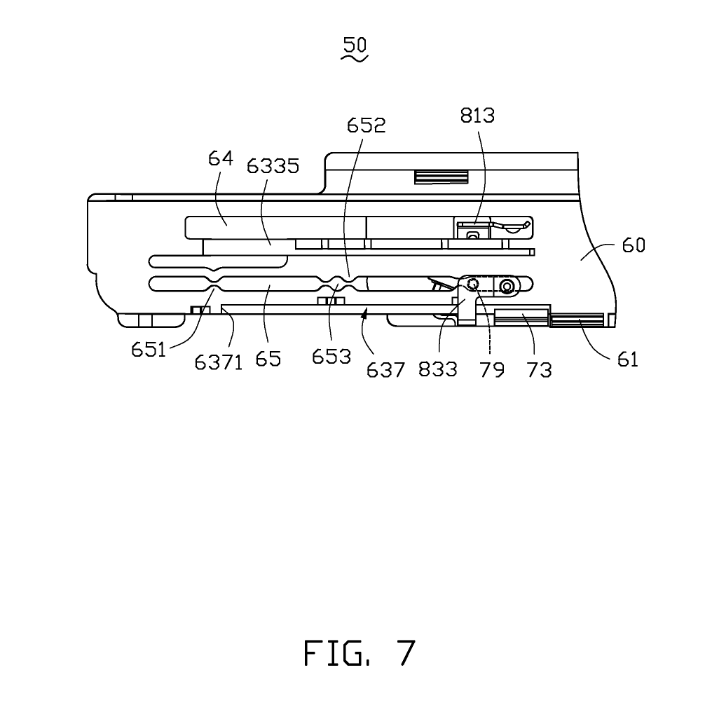

Referring to FIGS. 5-7, the sliding member 70 and the second conductive assembly 80 are slidable relative to the mounting plate 60 together in the sliding slot 65 and positioned in a first position, where the limiting portion 73 is engaged with the guiding piece 635 and abuts the first end 6371 of the guiding slot 637, and the sliding post 79 is blocked by the first blocking portions 651 adjacent to the first end 6371; a second position, where the limiting portion 73 is engaged with the guiding piece 635, and the sliding post 79 is engaged in the receiving portion 653; or a third position, where the limiting portion 73 is engaged with the guiding piece 635 and abuts the second end 6373 of the guiding slot 637, and the sliding post 79 is blocked by the first blocking portions 651 adjacent to the second end 6373.

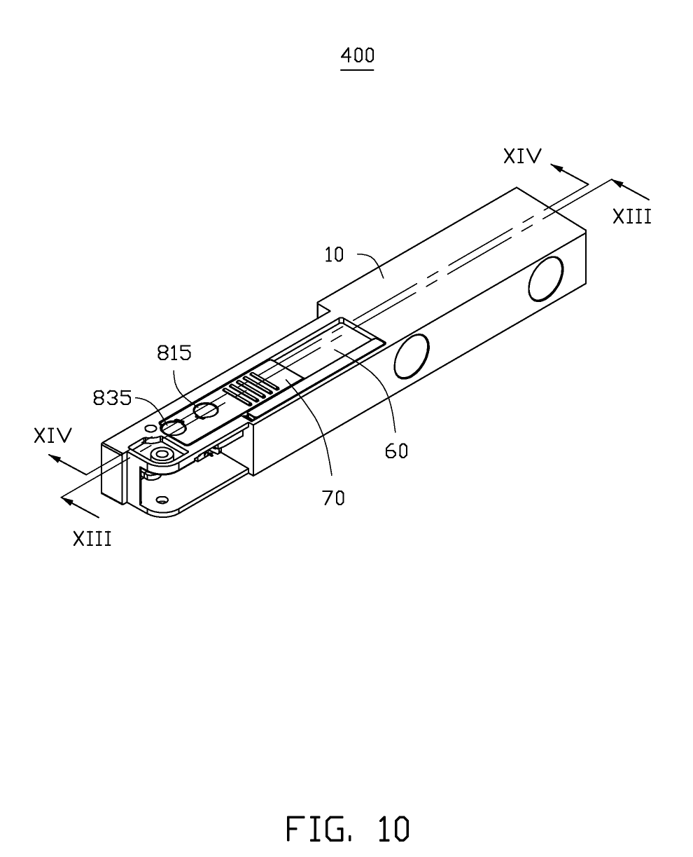

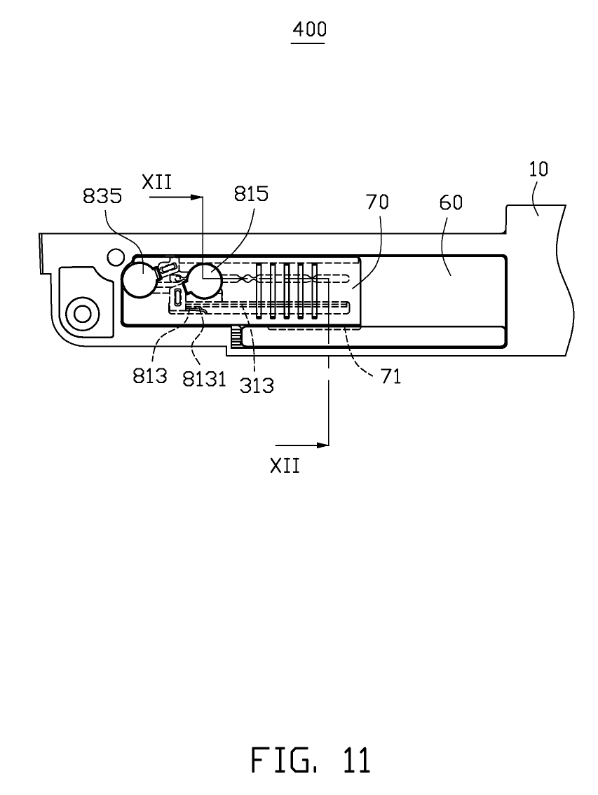

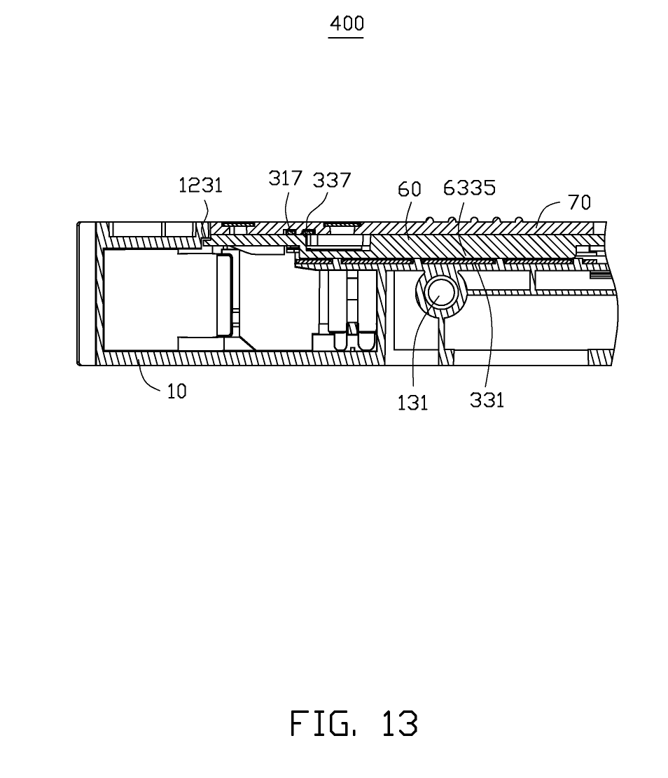

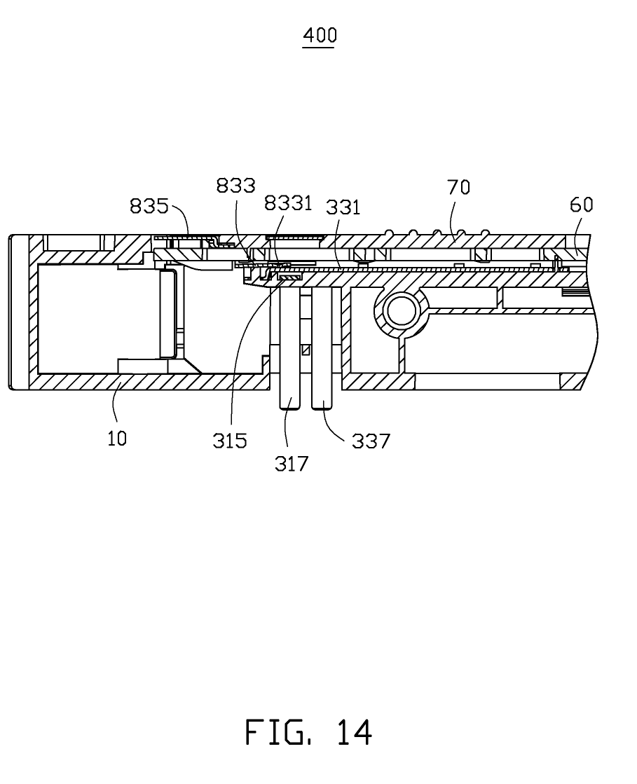

Referring to FIGS. 10, 11, 13, and 14, the first conductive assembly 30 is mounted in the frame 10. The first piece body 311 abuts the first wall piece 151, and the first connecting piece 317 is inserted through the first inserting hole 1533 to couple with the cable 500. The second piece body 331 abuts the second wall piece 152, and the second connecting piece 337 is inserted through the second inserting hole 1535 to couple with the cable 500. Each mounting post 18 is inserted into a corresponded first mounting hole 3111 or second mounting hole 3311.

The sliding assembly 50 is mounted in the recess portion 12. Each latching portion 61 is engaged in the latching hole 121. The blocking piece 62 abuts a bottom wall of the recess slot 123. The pressing portion 6335 resists the mounting wall 335. The first coupling portion 313 contacts the first elastic piece 81 through the first sliding slot 64, and the first protrusion 8131 abuts against the first coupling portion 313, so that the first elastic piece 81 is electronically coupled to the first resilient piece 31. The second protrusion 8331 abuts against the second piece body 331 to electronically couple the second elastic piece 83 to the second resilient piece 33.

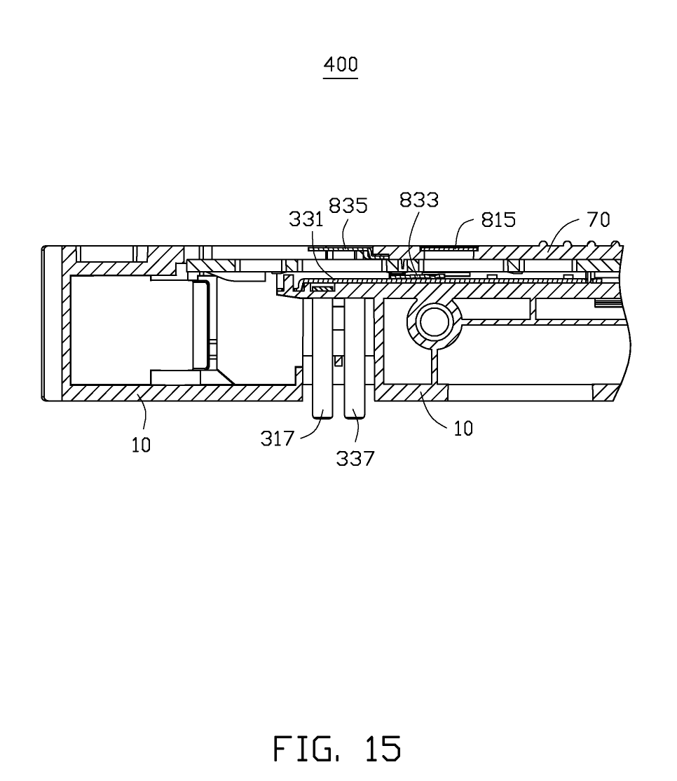

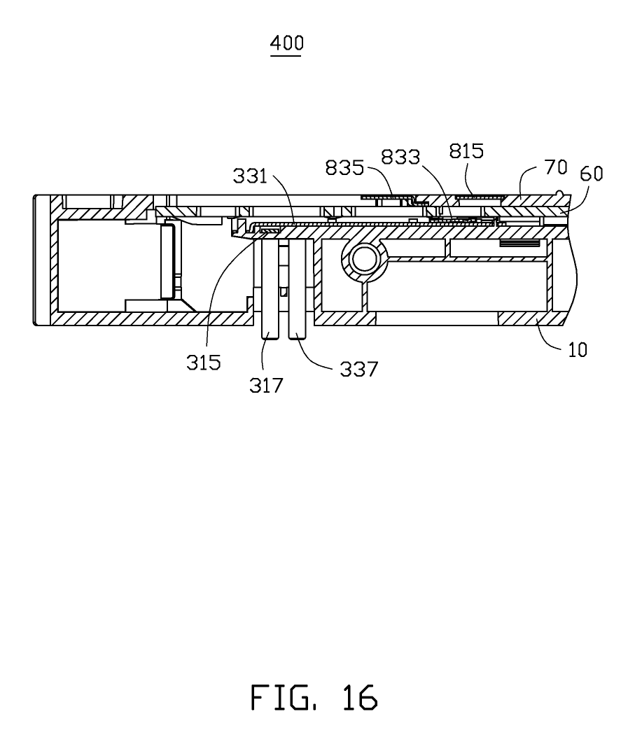

Referring to FIGS. 10, 11, and 13-16, the first conductive assembly 30 is mounted to the frame 10. The second conductive assembly 80 and the sliding member 70 are slidable relative to the frame 10 together. When the second conductive assembly 80 and the sliding member 70 are sliding, the first elastic piece 81 always contacts to the first resilient piece 31, and the second elastic piece 83 always contacts to the second resilient piece 33. Thus, the second conductive assembly 80 is slidable to adjust the positions of the first coupling piece 815 and the second coupling piece 835 to electronically couple the induction device 400 to the detection device in different positions.

The embodiments shown and described above are only examples. Many details are often found in the art such as the other features of an induction device and an electronic device. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. An induction device comprising:
a frame mountable to a rack with a detection unit;
a first conductive assembly mounted on the frame; and
a sliding assembly mounted to the rack and having a second conductive assembly;
wherein, the first conductive assembly is electronically attachable to an outside source;
wherein, the second conductive assembly is slidable relative to the frame and is electronically connected to the first conductive member; and
wherein, the second conductive assembly is configured to electronically couple with the detection unit.

2. The induction device of claim 1, wherein the first conductive assembly comprises a first resilient piece and a second resilient piece, and the second conductive assembly comprises a first elastic piece and a second elastic piece; the first elastic piece is electronically coupled to the first resilient piece, and the second elastic piece is electronically coupled to the second resilient piece;
and the first elastic piece and the second elastic piece are slidable relative to the first resilient piece and the second resilient piece.

3. The induction device of claim 2, wherein the sliding assembly further comprises a mounting plate and a sliding member secured to the mounting plate, the second conductive assembly is secured to the sliding member, the sliding member comprises a limiting portion and a sliding portion, the mounting plate defines a guiding slot for the limiting portion and a sliding slot for the sliding portion, and the second conductive assembly and the sliding member are slidable together on the mounting plate.

4. The induction device of claim 3, wherein the sliding member has a first receiving portion configured to receive the first elastic piece, a second receiving portion configured to receive the second elastic piece, and a sliding post extending between the first receiving portion and the second receiving portion; the mounting plate defines a first sliding slot and a second sliding slot, the first elastic piece is coupled to the first resilient piece through the first sliding slot, and the second elastic piece is coupled to the second resilient piece through the second sliding slot; and
the mounting plate further has a plurality pairs of blocking portions extending from opposites edges of the second sliding slot, and each pair of blocking portions is configured to stop the sliding post when the sliding post is slid in the second sliding slot.

5. The induction device of claim 4, wherein the mounting plate further comprises two pairs of second blocking portions located between adjacent two pairs of first blocking portions, and a receiving portion is defined between the two pairs of second blocking portions and configured to engage the sliding post therein.

6. The induction device of claim 5, wherein the first elastic piece comprises a first installation piece secured to the sliding member, a first connecting piece extending from a first end of the first installation piece, and a first coupling piece extending from a second end of the first installation piece; the second elastic piece comprises a second installation piece, a second connecting piece substantially parallel to the second installation piece, and a second coupling piece extending from an edge of the second installation piece; the first coupling piece contacts the first elastic piece through the first sliding slot, the second coupling piece and the second installation piece are located on opposite sides of the mounting plate, and second coupling piece contacts the second elastic piece.

7. The induction device of claim 6, wherein the first resilient piece comprises a first piece body and a first coupling portion extending from an edge of the first piece body; the first piece body is substantially perpendicular to the first coupling portion, and the first coupling portion contacts the first coupling piece; the second resilient piece comprises a second piece body and a mounting wall secured to the frame, the mounting wall is substantially perpendicular to the second piece body, and the second piece body contacts the second coupling piece.

8. The induction device of claim 7, wherein the mounting plate further comprises a pressing portion located between the first sliding slot and the second sliding slot, and the pressing portion resists the mounting wall and is substantially parallel to the second sliding slot.

9. The induction device of claim 7, wherein the frame has a recess portion receiving the sliding assembly, the recess portion has bottom wall, and the bottom wall has first wall piece securing the first resilient piece and a second wall piece securing the second resilient piece; the second wall piece extends upwards from the first wall piece; the first wall piece defines a first inserting hole, and the second wall piece defines a second inserting hole; and the first connecting piece extends through the first inserting hole, and the second connecting piece extends through the second inserting hole.

10. An induction device comprising:
a frame configured to be secured to a rack;
a first conductive assembly located in the frame; and
a sliding assembly comprising a mounting plate secured to the frame and a second conductive assembly;
wherein the second conductive assembly is slidable relative to the frame and alternatively mounted to the mounting plate in a first position, where the second conductive assembly electronically couples to the first conductive assembly and is configured to electronically couple to a first detection module, or a second position, where the second conductive assembly electronically couples to the first conductive assembly and is configured to electronically couple to a second detection module located in a different position from the first detection module.

11. The induction device of claim 10, wherein the first conductive assembly comprises a first resilient piece and a second resilient piece, and the second conductive assembly comprises a first elastic piece and a second elastic piece; the first elastic piece is electronically coupled to the first resilient piece, and the second elastic piece is electronically coupled to the second resilient piece;
and the first elastic piece and the second elastic piece are slidable relative to the first resilient piece and the second resilient piece.

12. The induction device of claim 11, wherein the sliding assembly further comprises a sliding member secured to the mounting plate, the second conductive assembly is secured to the sliding member, the sliding member comprises a limiting portion and a sliding portion, the mounting plate defines a guiding slot for the limiting portion and a sliding slot for the sliding portion, and the second conductive assembly and the sliding member are slidable together on the mounting plate.

13. The induction device of claim 12, wherein the sliding member has a first receiving portion configured to receive the first elastic piece, a second receiving portion configured to receive the second elastic piece, and a sliding post extending between the first receiving portion and the second receiving portion; the mounting plate defines a first sliding slot and a second sliding slot, the first elastic piece is coupled to the first resilient piece through the first sliding slot, and the second elastic piece is coupled to the second resilient piece through the second sliding slot; and
the mounting plate further has a plurality pairs of blocking portions extending from opposites edges of the second sliding slot, and each pair of blocking portions is configured to stop the sliding post when the sliding post is slid in the second sliding slot.

14. The induction device of claim 13, wherein the mounting plate further comprises two pairs of second blocking portions located between adjacent two pairs of first blocking portions, and a receiving portion is defined between the two pairs of second blocking portions and configured to engage the sliding post therein.

15. The induction device of claim 14, wherein the first elastic piece comprises a first installation piece secured to the sliding member, a first connecting piece extending from a first end of the first installation piece, and a first coupling piece extending from a second end of the first installation piece; the second elastic piece comprises a second installation piece, a second connecting piece substantially parallel to the second installation piece, and a second coupling piece extending from an edge of the second installation piece; the first coupling piece contacts the first elastic piece through the first sliding slot, the second coupling piece and the second installation piece are located on opposite sides of the mounting plate, and second coupling piece contacts the second elastic piece.

16. The induction device of claim 15, wherein the first resilient piece comprises a first piece body and a first coupling portion extending from an edge of the first piece body; the first piece body is substantially perpendicular to the first coupling portion, and the first coupling portion contacts the first coupling piece; the second resilient piece comprises a second piece body and a mounting wall secured to the frame, the mounting wall is substantially perpendicular to the second piece body, and the second piece body contacts the second coupling piece.

17. The induction device of claim 16, wherein the mounting plate further comprises a pressing portion located between the first sliding slot and the second sliding slot, and the pressing portion resists the mounting wall and is substantially parallel to the second sliding slot.

18. The induction device of claim 16, wherein the frame has a recess portion receiving the sliding assembly, the recess portion has bottom wall, and the bottom wall has first wall piece securing the first resilient piece and a second wall piece securing the second resilient piece; the second wall piece extends upwards from the first wall piece; the first wall piece defines a first inserting hole, and the second wall piece defines a second inserting hole; and the first connecting piece extends through the first inserting hole, and the second connecting piece extends through the second inserting hole.

19. An electronic device comprising:
a rack comprising a guiding rail; and
an induction device comprising:
a frame configured to be secured to the rack;
a first conductive assembly located in the frame; and
a sliding assembly mounted in the frame and comprising a second conductive assembly;
wherein the second conductive assembly is slidable relative to the frame and electronically couples to the first conductive assembly during sliding, and the second conductive assembly is configured to electronically couple to a detection module located in the guiding rail during sliding.

20. The induction device of claim 19, wherein the first conductive assembly comprises a first resilient piece and a second resilient piece, and the second conductive assembly comprises a first elastic piece and a second elastic piece; the first elastic piece is electronically coupled to the first resilient piece, and the second elastic piece is electronically coupled to the second resilient piece;
and the first elastic piece and the second elastic piece are slidable relative to the first resilient piece and the second resilient piece.
